(19) United States
(12) Patent Application Publication
(10) Pub. No.: US 2026/0173841 A1
(43) Pub. Date: Jun. 18, 2026

(54) ELECTRONIC PACKAGE, ELECTRONIC DEVICE AND MANUFACTURING METHOD THEREOF

(71) Applicant: SILICONWARE PRECISION INDUSTRIES CO., LTD., Taichung City (TW)

(72) Inventors: Yi-Min FU, Taichung City (TW); Chi-Ching HO, Taichung City (TW); Yu-Po WANG, Taichung City (TW)

(73) Assignee: SILICONWARE PRECISION INDUSTRIES CO., LTD., Taichung City (TW)

(21) Appl. No.: 19/201,503

(22) Filed: May 7, 2025

(30) Foreign Application Priority Data
Dec. 12, 2024 (TW) 113148430

(51) Int. Cl. H01L 23/00; H01L 23/31; H01L 23/48

(52) U.S. Cl. CPC H10W 20/20; H10W 74/111; H10W 72/248

(57) ABSTRACT

An electronic package is provided and includes a carrying structure, a wiring structure, an electronic structure, an encapsulation layer and a connecting element. The wiring structure is disposed on the carrying structure. The electronic structure is disposed on the wiring structure and includes a plurality of first conductive bumps and a plurality of second conductive bumps. The plurality of first conductive bumps are electrically connected to the wiring structure. The encapsulation layer is formed on the wiring structure and covers the electronic structure. The plurality of second conductive bumps are exposed from the encapsulation layer. The connecting element is disposed on the encapsulation layer and is electrically connected to the plurality of second conductive bumps. An electronic device having the electronic package and a manufacturing method of the electronic package are further provided.

### BACKGROUND

### 1. Technical Field

The present disclosure relates to a semiconductor device, and more particularly, to an electronic package and an electronic device having the electronic package that can improve transmission speed and a manufacturing method thereof.

### 2. Description of Related Art

As data networks scale to meet ever-increasing bandwidth requirements, disadvantages of using copper as an information channel become increasingly apparent. Signal attenuation and crosstalk caused by radiated electromagnetic energy are major obstacles encountered by designers of these systems. Signal attenuation and crosstalk can be mitigated to some extent through equalization, coding and shielding, but these techniques require considerable power, complexity and cable volume losses while providing only modest improvements in local area and very limited scalability. To get rid of these channel restrictions, optical communication has become the successor.

As shown in FIG. 1, a conventional optical transmission packaging structure 1 (a co-packaged connector [CPC]) includes a substrate structure 10, an electronic package 11 disposed on the substrate structure 10, and an optical module 12 disposed on the substrate structure 10, wherein the substrate structure 10 is a printed circuit board, the electronic package 11 has a circuit structure 110, an electronic component 111 and a connector 112, the circuit structure 110 is disposed on the substrate structure 10 via a plurality of conductive bumps, the electronic component 111 is an application-specific integrated circuit semiconductor chip and is disposed on the circuit structure 110, the connector 112 is disposed on the circuit structure 110 and is spaced apart from the electronic component 111, the optical module 12 has a photodiode, a transimpedance amplifier, a laser diode device, or a clock and data recovery device, and the optical module 12 is connected to the connector 112 via a transmission line/wire 13. However, the data transmission speed of the conventional optical transmission packaging structure 1 is still limited and will not be sufficient for the transmission of larger amounts of information in the future.

Therefore, how to overcome the aforementioned problems of the prior art has become an urgent issue to be solved.

### SUMMARY

In view of the aforementioned shortcomings of the prior art, the present disclosure provides an electronic package, which comprises: a carrying structure; a wiring structure disposed on the carrying structure; an electronic structure disposed on the wiring structure and including a plurality of first conductive bumps and a plurality of second conductive bumps, wherein the plurality of first conductive bumps are electrically connected to the wiring structure; an encapsulation layer formed on the wiring structure and covering the electronic structure, wherein the plurality of second conductive bumps are exposed from the encapsulation layer; and a connecting element disposed on the encapsulation layer and electrically connected to the plurality of second conductive bumps.

In the aforementioned electronic package, the electronic structure further includes an electronic body, the electronic body has a first side and a second side opposite to the first side, the plurality of first conductive bumps are formed on the first side, and the plurality of second conductive bumps are formed on the second side.

In the aforementioned electronic package, the electronic body has a plurality of conductive through-holes formed therein.

In the aforementioned electronic package, the plurality of second conductive bumps are electrically connected to the plurality of first conductive bumps via the plurality of conductive through-holes.

In the aforementioned electronic package, the electronic body is an application-specific integrated circuit semiconductor chip.

In the aforementioned electronic package, the connecting element is a connector for connecting transmission lines.

The aforementioned electronic package further comprises a circuit structure disposed between the encapsulation layer and the connecting element.

The present disclosure further provides an electronic device, which comprises: a substrate structure; the aforementioned electronic package disposed on the substrate structure; and an optical module disposed on the substrate structure and electrically connected to the connecting element via transmission lines.

In the aforementioned electronic device, the optical module includes a photodiode, a transimpedance amplifier, a laser diode device, or a clock and data recovery device.

The present disclosure further provides a method of manufacturing an electronic package, the method comprises: disposing an electronic structure on a wiring structure, wherein the electronic structure includes a plurality of first conductive bumps and a plurality of second conductive bumps, and the plurality of first conductive bumps are electrically connected to the wiring structure; forming an encapsulation layer on the wiring structure to cover the electronic structure, wherein the plurality of second conductive bumps are exposed from the encapsulation layer; disposing the wiring structure on a carrying structure; and disposing a connecting element on the encapsulation layer to be electrically connected to the plurality of second conductive bumps.

In the aforementioned method, the electronic structure further includes an electronic body, the electronic body has a first side and a second side opposite to the first side, the plurality of first conductive bumps are formed on the first side, and the plurality of second conductive bumps are formed on the second side.

In the aforementioned method, the electronic body has a plurality of conductive through-holes formed therein.

In the aforementioned method, the plurality of second conductive bumps are electrically connected to the plurality of first conductive bumps via the plurality of conductive through-holes.

In the aforementioned method, the electronic body is an application-specific integrated circuit semiconductor chip.

In the aforementioned method, the connecting element is a connector for connecting transmission lines.

The aforementioned method further comprises: after forming the encapsulation layer, forming a circuit structure on the encapsulation layer, then disposing the connecting element on the circuit structure.

In summary, the electronic package, the electronic device and the manufacturing method thereof of the present disclosure can allow the connecting element to be directly connected to the electronic structure, so that the transmission speed can be faster compared to the conventional structure. Further, the electronic package and the electronic device of the present disclosure can be manufactured by using existing semiconductor packaging processes without developing special processes or purchasing special equipment, so as to effectively reduce production cost and have high feasibility of technical implementation.

### BRIEF DESCRIPTION OF THE DRAWINGS

FIG. 1 is a schematic cross-sectional view showing a conventional optical transmission packaging structure.

FIG. 2A to FIG. 2H are schematic cross-sectional views illustrating a manufacturing method of an electronic package of the present disclosure.

FIG. 2I is a schematic view showing an application of the electronic package of

FIG. 2H of the present disclosure.

FIG. 3A to FIG. 3C are schematic cross-sectional views illustrating another manufacturing method of an electronic package of the present disclosure.

FIG. 3D is another schematic view showing an application of the electronic package of FIG. 3C of the present disclosure.

FIG. 4 is a schematic view showing an electronic device of the present disclosure.

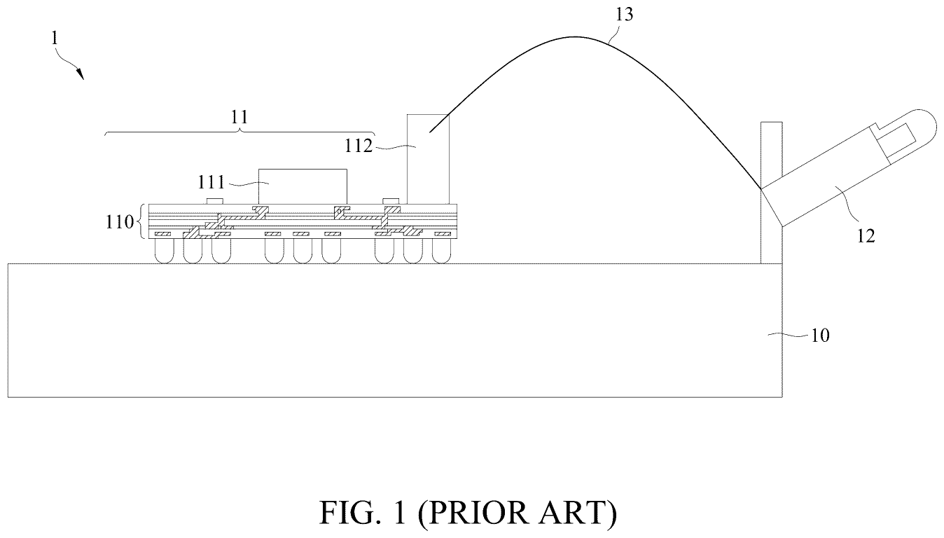

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

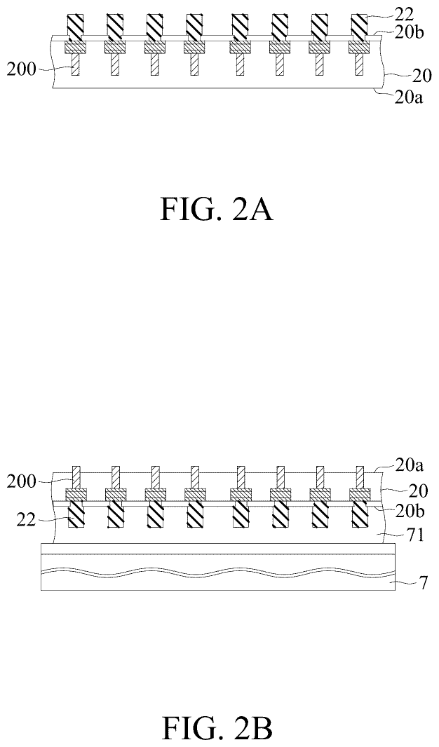

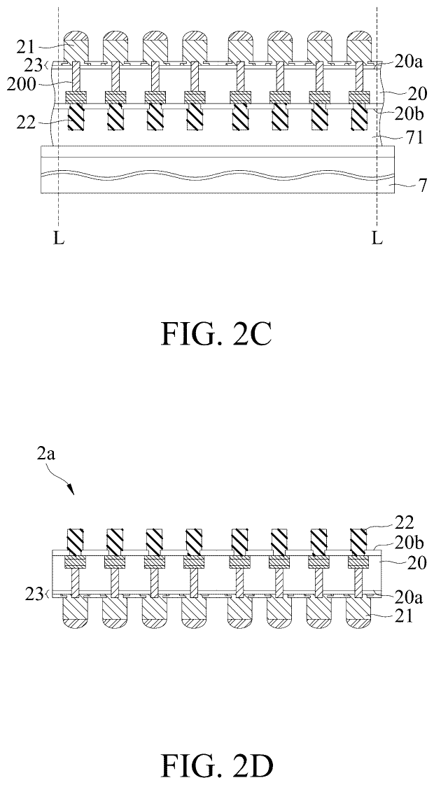

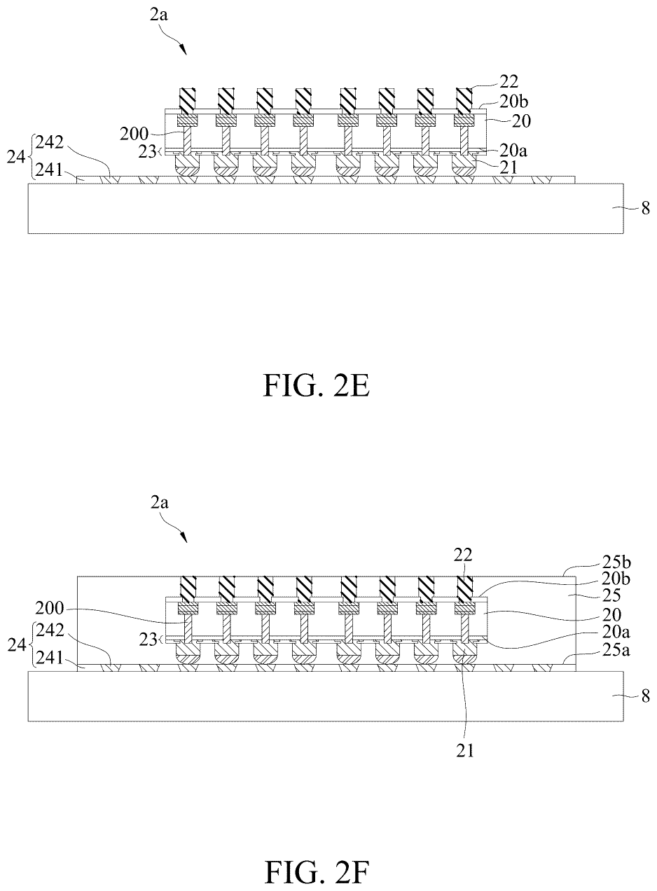

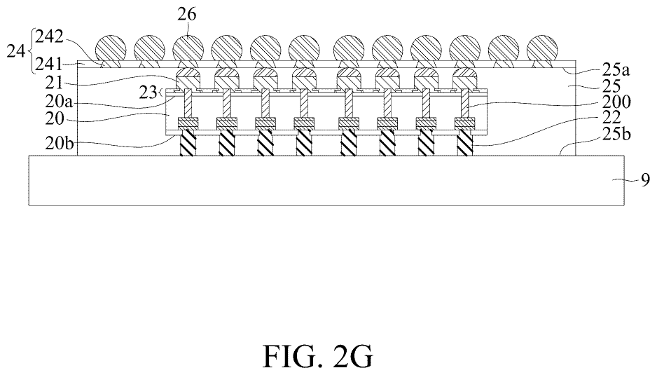

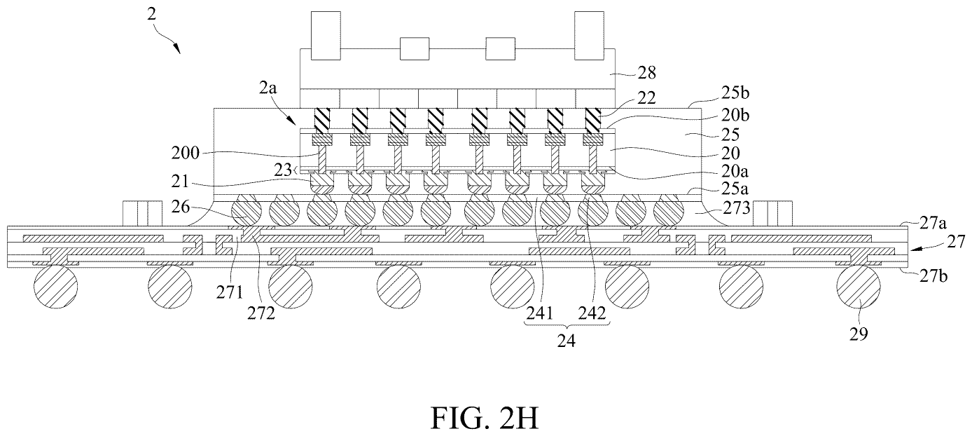

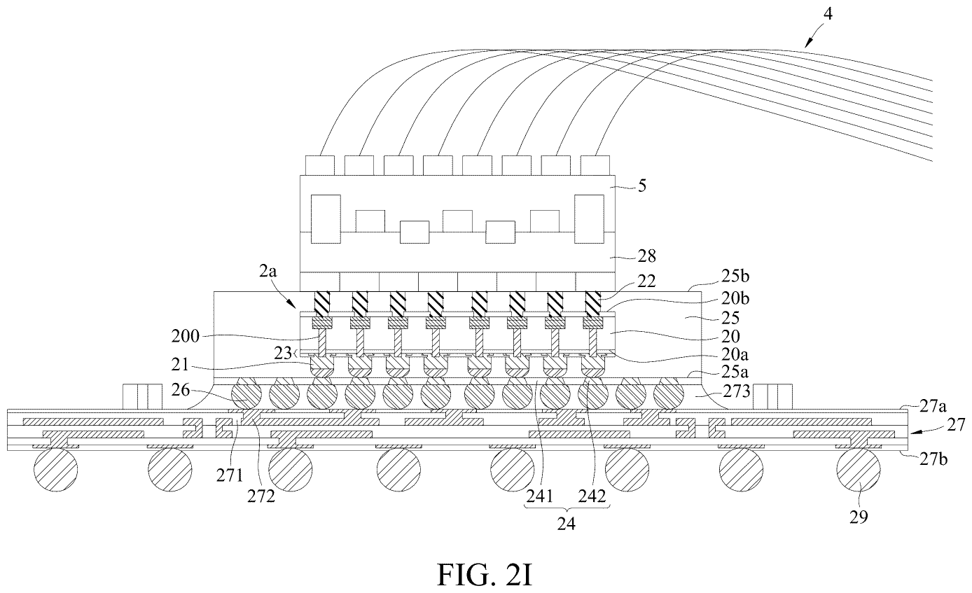

FIG. 2A to FIG. 2H are schematic cross-sectional views illustrating a manufacturing method of an electronic package 2 of the present disclosure.

As shown in FIG. 2A, an electronic body 20 and a plurality of second conductive bumps 22 are provided. The electronic body 20 has a first side 20a and a second side 20b opposite to the first side 20a, a plurality of conductive through-holes 200 are formed in the electronic body 20, and the plurality of second conductive bumps 22 are formed on the second side 20b of the electronic body 20 and are electrically connected to the plurality of conductive through-holes 200, wherein the conductive through-holes 200 are not exposed from the first side 20a of the electronic body 20.

In one embodiment, the electronic body 20 is an application-specific integrated circuit (ASIC) semiconductor chip. The conductive through-holes 200 can be, for example, conductive through-silicon vias (TSVs). The second conductive bumps 22 can be, for example, metal pillars such as copper pillars.

As shown in FIG. 2B, the second side 20b of the electronic body 20 is disposed on a carrying board 7, and the plurality of second conductive bumps 22 are embedded in a bonding layer 71 on the carrying board 7. Then, the first side 20a of the electronic body 20 is thinned (for example, a grinding/etching process is performed), so that the plurality of conductive through-holes 200 are exposed from the first side 20a of the electronic body 20.

As shown in FIG. 2C, a conductive circuit 23 is formed on the first side 20a of the electronic body 20, and a plurality of first conductive bumps 21 are formed on the conductive circuit 23, such that the plurality of first conductive bumps 21 are electrically connected to the plurality of second conductive bumps 22 via the plurality of conductive through-holes 200.

In one embodiment, the plurality of first conductive bumps 21 can include, for example, copper pillars and solder materials, and the conductive circuit 23 can include at least one insulating layer and at least one redistribution layer (RDL) formed on the insulating layer, wherein the outermost insulating layer can be used as a solder-resist layer, the outermost redistribution layer (made of such as copper) can be exposed from the solder-resist layer to serve as electrical contact pads (such as μ-pads or micro pads), and an under bump metallurgy (UBM) layer made of such as copper can be formed on the electrical contact pads to facilitate the bonding to the plurality of first conductive bumps 21.

As shown in FIG. 2D, the carrying board 7 is removed, and a singulation process is performed along a cutting path L as shown in FIG. 2C to attain an electronic structure 2a.

As shown in FIG. 2E, a carrier 8 is provided. A wiring structure 24 (e.g., a routing structure) is formed on the carrier 8, and the electronic structure 2a is disposed on the wiring structure 24. It should be understood that there is no sequential order between the manufacturing methods of the wiring structure 24 and the electronic structure 2a.

The carrier 8 is, for example, a board made of semiconductor material (such as silicon or glass). The wiring structure 24 includes at least one dielectric layer 241 and at least one circuit layer 242 bonded to the dielectric layer 241. The dielectric layer 241 can be made of, for example, polybenzoxazole (PBO), polyimide (PI), prepreg (PP), or other dielectric materials. The circuit layer 242 and the dielectric layer 241 can be formed by using a redistribution layer (RDL) process, and the circuit layer 242 can be made of copper. The electronic structure 2a is disposed on the circuit layer 242 of the wiring structure 24 via the plurality of first conductive bumps 21, such that the plurality of first conductive bumps 21 are electrically connected to the circuit layer 242.

As shown in FIG. 2F, an encapsulation layer 25 is formed on the wiring structure 24 to encapsulate the electronic structure 2a. It should be understood that part of the material of the encapsulation layer 25 and part of the material of each of the second conductive bumps 22 can be removed by a leveling process (grinding), so that the end surfaces of the plurality of second conductive bumps 22 are exposed from and flush with the surface of the encapsulation layer 25.

In one embodiment, the encapsulation layer 25 has a first side 25a and a second side 25b opposite to the first side 25a, wherein the first side 25a of the encapsulation layer 25 is bonded to the wiring structure 24, and the end surfaces of the plurality of second conductive bumps 22 are exposed from the second side 25b of the encapsulation layer 25. The encapsulation layer 25 is made of insulating material such as polyimide (PI), dry film, epoxy molding colloid, or epoxy molding compound. The encapsulation layer 25 can be formed on the wiring structure 24 by liquid compound, lamination, or compression molding.

As shown in FIG. 2G, the second side 25b of the encapsulation layer 25 is bonded to another carrier 9, and the carrier 8 is removed.

In one embodiment, the carrier 9 is, for example, a board made of semiconductor material (such as silicon or glass), such that the second side 25b of the encapsulation layer 25 and the end surfaces of the plurality of second conductive bumps 22 are bonded to the carrier 9. Then, the carrier 8 is removed to expose the wiring structure 24. Afterwards, a plurality of conductive components 26 are formed on the wiring structure 24, such that the plurality of conductive components 26 are electrically connected to the circuit layer 242 of the wiring structure 24, wherein the conductive components 26 can be, for example, copper bumps or solder bumps.

As shown in FIG. 2H, the electronic structure 2a and the wiring structure 24 are disposed on a carrying structure 27 via the plurality of conductive components 26, and an underfill 273 is filled between the wiring structure 24 and the carrying structure 27 to encapsulate the plurality of conductive components 26. Then, the carrier 9 is removed to expose the second side 25b of the encapsulation layer 25 and the end surfaces of the plurality of second conductive bumps 22. Afterwards, a connecting element 28 is disposed on the second side 25b of the encapsulation layer 25, and a plurality of conductors 29 are disposed on the other side of the carrying structure 27 to attain the electronic package 2 of the present disclosure, wherein the conductors 29 can be, for example, copper bumps or solder bumps.

In one embodiment, the carrying structure 27 has a first side 27a and a second side 27b opposite to the first side 27a, the plurality of conductive components 26 are connected to the first side 27a of the carrying structure 27, and the plurality of conductors 29 are connected to the second side 27b of the carrying structure 27. The carrying structure 27 includes at least one dielectric layer 271 and at least one circuit layer 272 bonded to the dielectric layer 271. The dielectric layer 271 can be made of, for example, polybenzoxazole (PBO), polyimide (PI), prepreg (PP), or other dielectric materials. The circuit layer 272 and the dielectric layer 271 can be formed by using a redistribution layer (RDL) process. The circuit layer 272 can be electrically connected to the plurality of conductive components 26 and the plurality of conductors 29, and the circuit layer 272 can be made of copper.

The connecting element 28 is electrically connected to the plurality of second conductive bumps 22. The connecting element 28 can be, for example, a connector for connecting transmission lines/wires. As shown in FIG. 2I, the connecting element 28 can be coupled to a joint 5 at the ends of transmission lines/wires 4.

The present disclosure further provides an electronic package 2, which comprises a carrying structure 27, a wiring structure 24, an electronic structure 2a, an encapsulation layer 25 and a connecting element 28.

The carrying structure 27 has a first side 27a and a second side 27b opposite to the first side 27a. A plurality of conductors 29 are disposed on the second side 27b of the carrying structure 27. The carrying structure 27 includes a dielectric layer 271 and a circuit layer 272 bonded to the dielectric layer 271. The circuit layer 272 can be electrically connected to the plurality of conductors 29.

The wiring structure 24 is disposed on the first side 27a of the carrying structure 27 via a plurality of conductive components 26. An underfill 273 is disposed between the wiring structure 24 and the carrying structure 27 and encapsulates the plurality of conductive components 26. The wiring structure 24 includes a dielectric layer 241 and a circuit layer 242 bonded to the dielectric layer 241. The plurality of conductive components 26 are electrically connected to the circuit layers 242, 272.

The electronic structure 2a is disposed on the wiring structure 24. In one embodiment, the electronic structure 2a includes an electronic body 20, a plurality of first conductive bumps 21, a plurality of second conductive bumps 22 and a conductive circuit 23.

The electronic body 20 has a first side 20a and a second side 20b opposite to the first side 20a. A plurality of conductive through-holes 200 communicating the first side 20a and the second side 20b are formed in the electronic body 20. The plurality of second conductive bumps 22 are formed on the second side 20b of the electronic body 20 and are electrically connected to the plurality of conductive through-holes 200. The conductive circuit 23 is formed on the first side 20a of the electronic body 20, and the plurality of first conductive bumps 21 are formed on the conductive circuit 23, such that the plurality of first conductive bumps 21 are electrically connected to the plurality of second conductive bumps 22 via the plurality of conductive through-holes 200. The electronic structure 2a is disposed on the circuit layer 242 of the wiring structure 24 via the plurality of first conductive bumps 21, so that the plurality of first conductive bumps 21 are electrically connected to the circuit layer 242.

In one embodiment, the electronic body 20 is an application-specific integrated circuit semiconductor chip.

In one embodiment, the conductive circuit 23 can include at least one insulating layer and at least one redistribution layer (RDL) formed on the insulating layer, wherein the outermost insulating layer can be used as a solder-resist layer, the outermost redistribution layer (made of such as copper) can be exposed from the solder-resist layer to serve as electrical contact pads (such as μ-pads or micro pads), and an under bump metallurgy (UBM) layer made of such as copper can be formed on the electrical contact pads to facilitate the bonding to the plurality of first conductive bumps 21.

The encapsulation layer 25 has a first side 25a and a second side 25b opposite to the first side 25a. The first side 25a of the encapsulation layer 25 is bonded to the wiring structure 24, and the electronic structure 2a is encapsulated by the encapsulation layer 25. End surfaces of the plurality of second conductive bumps 22 are exposed from and flush with the second side 25b of the encapsulation layer 25.

The connecting element 28 is disposed on the second side 25b of the encapsulation layer 25 and is electrically connected to the plurality of second conductive bumps 22. In one embodiment, the connecting element 28 is a connector for connecting transmission lines/wires.

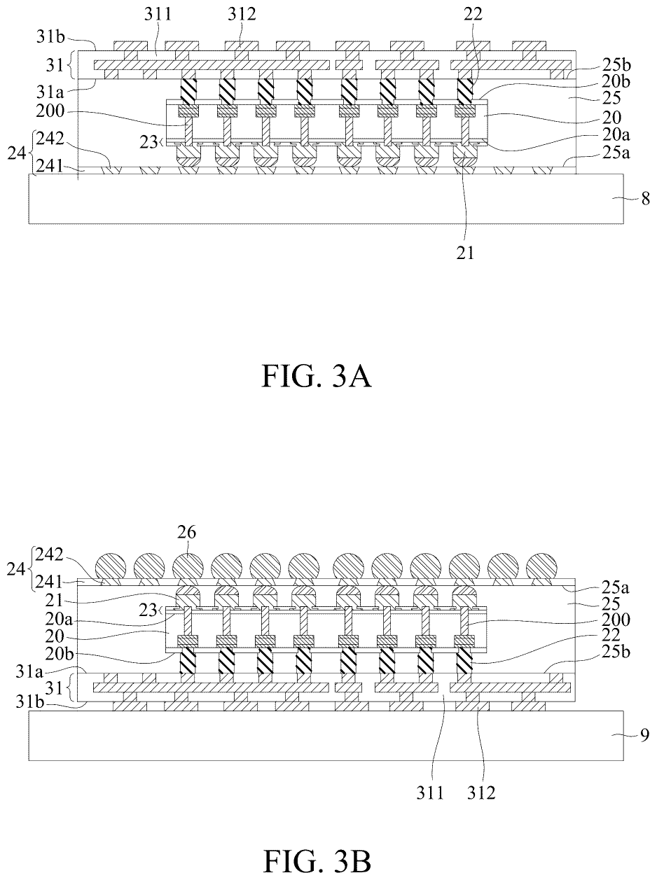

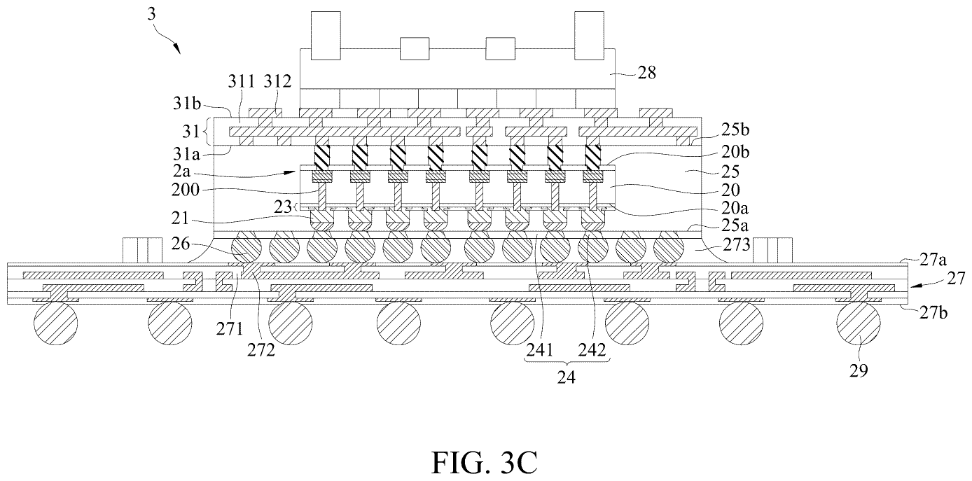

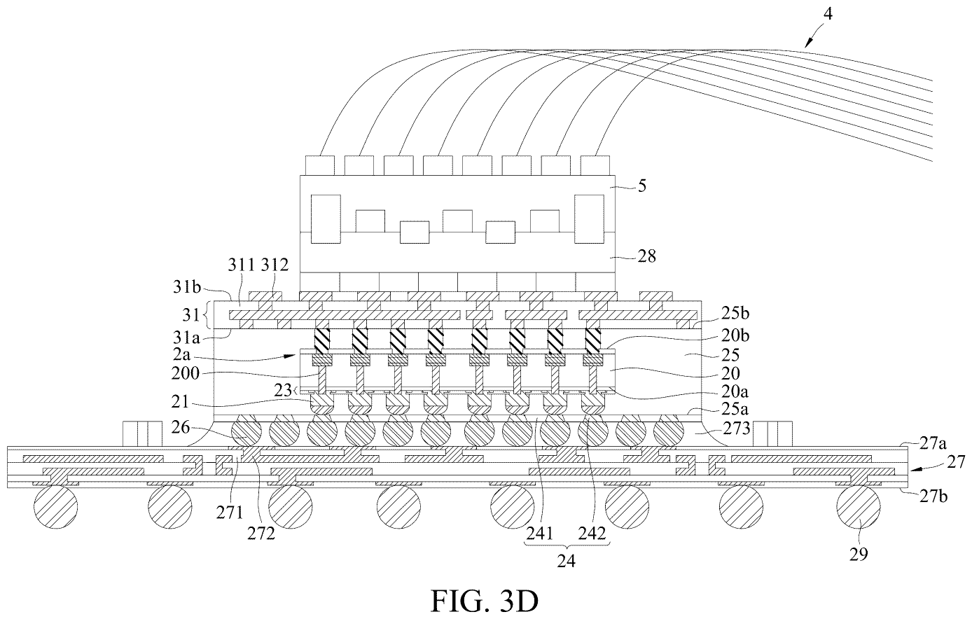

FIG. 3A to FIG. 3C are schematic cross-sectional views illustrating a manufacturing method of an electronic package 3 of the present disclosure, wherein the manufacturing method of the electronic structure 2a of this embodiment is the same as the previous embodiment, and the only difference between this embodiment and the previous embodiment is the circuit structure 31. Only the differences between this embodiment and the previous embodiment are described below, and the same technical content will not be repeated here.

As shown in FIG. 3A, following the manufacturing process illustrated in FIG. 2F, a circuit structure 31 is formed on the second side 25b of the encapsulation layer 25.

In one embodiment, the circuit structure 31 has a first side 31a and a second side 31b opposite to the first side 31a, and the first side 31a of the circuit structure 31 is disposed on the second side 25b of the encapsulation layer 25. The circuit structure 31 includes at least one dielectric layer 311 and at least one circuit layer 312 bonded to the dielectric layer 311. The dielectric layer 311 can be made of, for example, polybenzoxazole (PBO), polyimide (PI), prepreg (PP), or other dielectric materials. The circuit layer 312 and the dielectric layer 311 can be formed by using a redistribution layer (RDL) process, and the circuit layer 312 can be made of copper. The plurality of second conductive bumps 22 are electrically connected to the circuit layer 312 exposed from the first side 31a of the circuit structure 31. It should be understood that the number of layers of the dielectric layer 311 and the circuit layer 312 can be designed according to requirements.

As shown in FIG. 3B, the second side 31b of the circuit structure 31 is bonded to another carrier 9, and the carrier 8 is removed to expose the wiring structure 24. Afterwards, a plurality of conductive components 26 are formed on the wiring structure 24, such that the plurality of conductive components 26 are electrically connected to the circuit layer 242 of the wiring structure 24.

As shown in FIG. 3C, the electronic structure 2a, the wiring structure 24 and the circuit structure 31 are disposed on a carrying structure 27 via the plurality of conductive components 26. Then, the carrier 9 is removed to expose the second side 31b of the circuit structure 31. Afterwards, a connecting element 28 is disposed on the second side 31b of the circuit structure 31, and a plurality of conductors 29 are disposed on the carrying structure 27 to attain the electronic package 3 of the present disclosure, wherein the connecting element 28 is electrically connected to the circuit layer 312 of the circuit structure 31.

In one embodiment, the connecting element 28 can be, for example, a connector for connecting transmission lines/wires. As shown in FIG. 3D, the connecting element 28 can be coupled to a joint 5 at the ends of transmission lines/wires 4.

The present disclosure further provides an electronic package 3, which comprises a carrying structure 27, a wiring structure 24, an electronic structure 2a, an encapsulation layer 25, a circuit structure 31 and a connecting element 28.

The carrying structure 27 has a first side 27a and a second side 27b opposite to the first side 27a. A plurality of conductors 29 are disposed on the second side 27b of the carrying structure 27. The carrying structure 27 includes a dielectric layer 271 and a circuit layer 272 bonded to the dielectric layer 271. The circuit layer 272 can be electrically connected to the plurality of conductors 29.

The wiring structure 24 is disposed on the first side 27a of the carrying structure 27 via a plurality of conductive components 26. An underfill 273 is disposed between the wiring structure 24 and the carrying structure 27 and encapsulates the plurality of conductive components 26. The wiring structure 24 includes a dielectric layer 241 and a circuit layer 242 bonded to the dielectric layer 241. The plurality of conductive components 26 are electrically connected to the circuit layers 242, 272.

The electronic structure 2a is disposed on the wiring structure 24. In one embodiment, the electronic structure 2a includes an electronic body 20, a plurality of first conductive bumps 21, a plurality of second conductive bumps 22 and a conductive circuit 23.

The electronic body 20 has a first side 20a and a second side 20b opposite to the first side 20a. A plurality of conductive through-holes 200 communicating the first side 20a and the second side 20b are formed in the electronic body 20. The plurality of second conductive bumps 22 are formed on the second side 20b of the electronic body 20 and are electrically connected to the plurality of conductive through-holes 200. The conductive circuit 23 is formed on the first side 20a of the electronic body 20, and the plurality of first conductive bumps 21 are formed on the conductive circuit 23, such that the plurality of first conductive bumps 21 are electrically connected to the plurality of second conductive bumps 22 via the plurality of conductive through-holes 200. The electronic structure 2a is disposed on the circuit layer 242 of the wiring structure 24 via the plurality of first conductive bumps 21, so that the plurality of first conductive bumps 21 are electrically connected to the circuit layer 242.

In one embodiment, the electronic body 20 is an application-specific integrated circuit semiconductor chip.

In one embodiment, the conductive circuit 23 can include at least one insulating layer and at least one redistribution layer (RDL) formed on the insulating layer, wherein the outermost insulating layer can be used as a solder-resist layer, the outermost redistribution layer (made of such as copper) can be exposed from the solder-resist layer to serve as electrical contact pads (such as μ-pads or micro pads), and an under bump metallurgy (UBM) layer made of such as copper can be formed on the electrical contact pads to facilitate the bonding to the plurality of first conductive bumps 21.

The encapsulation layer 25 has a first side 25a and a second side 25b opposite to the first side 25a. The first side 25a of the encapsulation layer 25 is bonded to the wiring structure 24, and the electronic structure 2a is encapsulated by the encapsulation layer 25. End surfaces of the plurality of second conductive bumps 22 are exposed from and flush with the second side 25b of the encapsulation layer 25.

The circuit structure 31 has a first side 31a and a second side 31b opposite to the first side 31a, and the first side 31a of the circuit structure 31 is disposed on the second side 25b of the encapsulation layer 25. The circuit structure 31 includes a dielectric layer 311 and a circuit layer 312 bonded to the dielectric layer 311, and the plurality of second conductive bumps 22 are electrically connected to the circuit layer 312 exposed from the first side 31a of the circuit structure 31.

The connecting element 28 is disposed on the second side 31b of the circuit structure 31 and is electrically connected to the circuit layer 312 and the plurality of second conductive bumps 22. In one embodiment, the connecting element 28 is a connector for connecting transmission lines/wires.

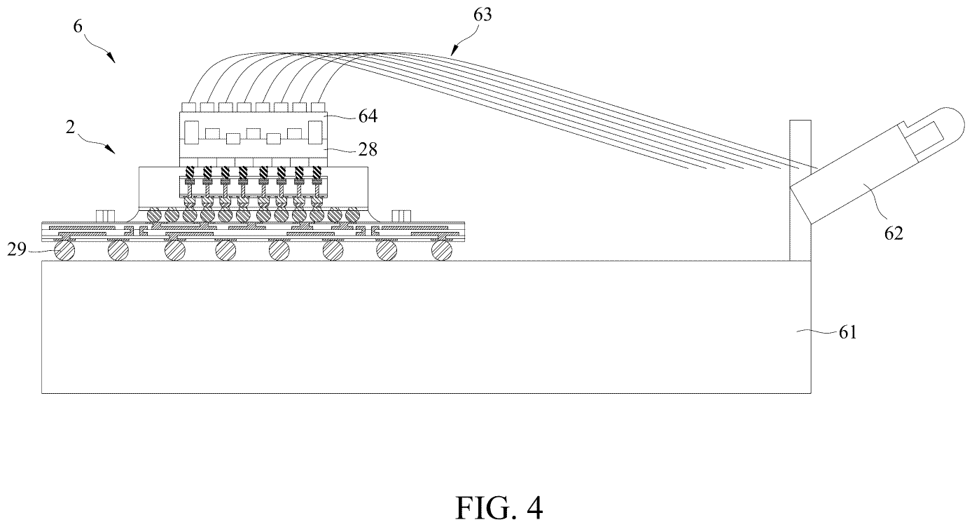

FIG. 4 is a schematic view showing an electronic device 6 of the present disclosure. The electronic device 6 is used to dispose the aforementioned electronic package 2, 3.

Taking the electronic package 2 as an example, as shown in FIG. 4, the electronic device 6 comprises a substrate structure 61, an optical module 62 and an electronic package 2. The electronic package 2 is disposed on the substrate structure 61 via the plurality of conductors 29. The optical module 62 is disposed on the substrate structure 61 and is spaced apart from the electronic package 2. The connecting element 28 of the electronic package 2 can be coupled to a joint 64 at the ends of transmission lines/wires 63 to communicate with the optical module 62.

In one embodiment, the substrate structure 61 can be, for example, a packaging substrate having a core layer and a circuit layer, a coreless circuit structure, or a printed circuit board (PCB).

In one embodiment, the optical module 62 includes a photodetector diode (a photodiode [PD]), a transimpedance amplifier (TIA), a laser driver (a laser diode device [LDD]), or a clock and data recovery (CDR) device.

To sum up, the electronic package, the electronic device and the manufacturing method thereof of the present disclosure can allow the connecting element to be directly connected to the electronic structure, so that the transmission speed can be faster compared to the conventional structure. Further, the electronic package and the electronic device of the present disclosure can be manufactured by using existing semiconductor packaging processes without developing special processes or purchasing special equipment, so as to effectively reduce production cost and have high feasibility of technical implementation.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrying structure;
a wiring structure disposed on the carrying structure;
an electronic structure disposed on the wiring structure and including a plurality of first conductive bumps and a plurality of second conductive bumps, wherein the plurality of first conductive bumps are electrically connected to the wiring structure;
an encapsulation layer formed on the wiring structure and covering the electronic structure, wherein the plurality of second conductive bumps are exposed from the encapsulation layer; and
a connecting element disposed on the encapsulation layer and electrically connected to the plurality of second conductive bumps.

2. The electronic package of claim 1, wherein the electronic structure further includes an electronic body, the electronic body has a first side and a second side opposite to the first side, the plurality of first conductive bumps are formed on the first side, and the plurality of second conductive bumps are formed on the second side.

3. The electronic package of claim 2, wherein the electronic body has a plurality of conductive through-holes formed therein.

4. The electronic package of claim 3, wherein the plurality of second conductive bumps are electrically connected to the plurality of first conductive bumps via the plurality of conductive through-holes.

5. The electronic package of claim 2, wherein the electronic body is an application-specific integrated circuit semiconductor chip.

6. The electronic package of claim 1, wherein the connecting element is a connector for connecting transmission lines.

7. The electronic package of claim 1, further comprising a circuit structure disposed between the encapsulation layer and the connecting element.

8. An electronic device, comprising:
a substrate structure;
the electronic package of claim 1 disposed on the substrate structure; and
an optical module disposed on the substrate structure and electrically connected to the connecting element via transmission lines.

9. The electronic device of claim 8, wherein the optical module includes a photodiode, a transimpedance amplifier, a laser diode device, or a clock and data recovery device.

10. An electronic device, comprising:
a substrate structure;
the electronic package of claim 2 disposed on the substrate structure; and
an optical module disposed on the substrate structure and electrically connected to the connecting element via transmission lines.

11. The electronic device of claim 10, wherein the optical module includes a photodiode, a transimpedance amplifier, a laser diode device, or a clock and data recovery device.

12. An electronic device, comprising:
a substrate structure;
the electronic package of claim 3 disposed on the substrate structure; and
an optical module disposed on the substrate structure and electrically connected to the connecting element via transmission lines.

13. The electronic device of claim 12, wherein the optical module includes a photodiode, a transimpedance amplifier, a laser diode device, or a clock and data recovery device.

14. An electronic device, comprising:
a substrate structure;
the electronic package of claim 4 disposed on the substrate structure; and
an optical module disposed on the substrate structure and electrically connected to the connecting element via transmission lines.

15. The electronic device of claim 14, wherein the optical module includes a photodiode, a transimpedance amplifier, a laser diode device, or a clock and data recovery device.

16. An electronic device, comprising:
a substrate structure;
the electronic package of claim 5 disposed on the substrate structure; and
an optical module disposed on the substrate structure and electrically connected to the connecting element via transmission lines.

17. The electronic device of claim 16, wherein the optical module includes a photodiode, a transimpedance amplifier, a laser diode device, or a clock and data recovery device.

18. An electronic device, comprising:
a substrate structure;
the electronic package of claim 6 disposed on the substrate structure; and
an optical module disposed on the substrate structure and electrically connected to the connecting element via transmission lines.

19. The electronic device of claim 18, wherein the optical module includes a photodiode, a transimpedance amplifier, a laser diode device, or a clock and data recovery device.

20. An electronic device, comprising:
a substrate structure;
the electronic package of claim 7 disposed on the substrate structure; and
an optical module disposed on the substrate structure and electrically connected to the connecting element via transmission lines.

21. The electronic device of claim 20, wherein the optical module includes a photodiode, a transimpedance amplifier, a laser diode device, or a clock and data recovery device.

22. A method of manufacturing an electronic package, comprising:
disposing an electronic structure on a wiring structure, wherein the electronic structure includes a plurality of first conductive bumps and a plurality of second conductive bumps, and the plurality of first conductive bumps are electrically connected to the wiring structure;
forming an encapsulation layer on the wiring structure to cover the electronic structure, wherein the plurality of second conductive bumps are exposed from the encapsulation layer;
disposing the wiring structure on a carrying structure; and
disposing a connecting element on the encapsulation layer to be electrically connected to the plurality of second conductive bumps.

23. The method of claim 22, wherein the electronic structure further includes an electronic body, the electronic body has a first side and a second side opposite to the first side, the plurality of first conductive bumps are formed on the first side, and the plurality of second conductive bumps are formed on the second side.

24. The method of claim 23, wherein the electronic body has a plurality of conductive through-holes formed therein.

25. The method of claim 24, wherein the plurality of second conductive bumps are electrically connected to the plurality of first conductive bumps via the plurality of conductive through-holes.

26. The method of claim 23, wherein the electronic body is an application-specific integrated circuit semiconductor chip.

27. The method of claim 22, wherein the connecting element is a connector for connecting transmission lines.

28. The method of claim 22, further comprising: after forming the encapsulation layer, forming a circuit structure on the encapsulation layer, then disposing the connecting element on the circuit structure.
